(19) United States
(12) Patent Application Publication
(10) Pub. No.: US 2013/0277855 A1
(43) Pub. Date: Oct. 24, 2013

(54) HIGH DENSITY 3D PACKAGE

(71) Applicants: Terry (Teckgyu) Kang, San Jose, CA (US); Abraham F. Yee, Cupertino, CA (US)

(72) Inventors: Terry (Teckgyu) Kang, San Jose, CA (US); Abraham F. Yee, Cupertino, CA (US)

(21) Appl. No.: 13/455,080

(22) Filed: Apr. 24, 2012

(51) Int. Cl. H01L 23/48; H01L 23/12; H01L 21/56; H01L 21/58

(52) U.S. Cl. 257/774; 438/108; 257/E23.011; 257/E23.003; 257/E21.505; 257/E21.502

(57) ABSTRACT

Embodiments of the present provide an integrated circuit system, which includes an interposer having a plurality of electrical conductive vias running through the interposer, one or more high-power chips mounted on a first surface of the interposer, wherein the one or more high-power chips generate at least 10 W of heat during normal operation, one or more low-power chips mounted on a second surface of the interposer, wherein the one or more low-power chips generate less than 5 W of heat during normal operation, and the first surface and the second surface are opposite and substantially parallel to each other, and an encapsulating material formed over and configured to encapsulate the one or more high-power chips and the one or more low-power chips. Since low-power chips and high-power chips are respectively mounted on front side and back side of the interposer, the footprint of the interposer and manufacturing cost associated therewith is reduced.

### BACKGROUND OF THE INVENTION

1. Field of the Invention

Embodiments of the present invention relate generally to integrated circuit chip packaging and, more specifically, to a three-dimensional system-in-package with a high power chip and a low power chip.

2. Description of the Related Art

The dimensions of state of the art electronic devices are ever decreasing. To reduce the dimensions of electronic devices, the structures by which the microprocessors, memory devices, and other semiconductor devices are packaged and assembled with circuit boards must become more compact.

In the packaging of integrated circuit chips, numerous assembling techniques have been developed to reduce the overall size of assemblies of the integrated circuits and circuit boards. Flip-chip bonding technique, for example, is one of the assembly approaches used to provide the integrated circuit package system with improved integration density. FIG. 1 illustrates a schematic sectional view of a conventional flip-chip package structure 100. The flip-chip structure 100 typically includes semiconductor devices 102, such as high-power chips 102a and low-power chips 102b that are mounted by their back surface on a top surface of an interposer 104. The interposer 104 is bounded directly to a top surface of a package substrate 106 with solder bumps 108. The package substrate 106 is then mounted onto a printed circuit board (PCB) 110 with solder balls 112, enabling electrical connections between the semiconductor devices 102 and the PCB 110. Flip-chip package structure offers the advantage of interconnecting semiconductor devices to external circuitry with reduced package size and shorter interconnection distances compared with integrated circuit package systems using a traditional wire-bonding technique, in which semiconductor devices (such as high/low-power chips) are wire bonded to a package substrate with relatively thick metal wires and corresponding bonding pads carried on the package substrate.

One disadvantage of the arrangement of the package structure shown in FIG. 1 is that high-power chips 102a and low-power chips 102b are mounted onto the same side of the interposer in order to achieve greater packaging density of integrated circuits. Therefore, a much larger footprint of the interposer is required. Further, the process of fabricating an interposer, particularly a through-silicon via (TSV)-based interposer, is complicated and very expensive as it provides vertical electrical interconnections between semiconductor devices and the underlying PCB by use of conductive vias (e.g., conductive vias 116b) running through the interposer, and in-plane electrical interconnections between semiconductor devices which are arranged horizontally along-side by use of conductive connections (e.g., conductive connections 116a). Existing multi-die packages not only increase the footprint of the interposer and thus impose a heavier routing burden on the package substrate, but also the cost associated with interposer fabrication due to high complexity of the interposer and manufacturing challenges such as bump pitch limitations, especially when seeking to combine different integrated circuits vertically in a single package.

Therefore, there is a need in the art for a cost-effective package system having a greater density of integrated circuits with a corresponding reduction in package size and interconnection distances.

### SUMMARY OF THE INVENTION

One embodiment of the present invention provides an integrated circuit system, which generally includes an interposer having a plurality of electrical conductive vias running through the interposer, one or more high-power chips mounted on a first surface of the interposer, wherein the one or more high-power chips generate at least 10 W of heat during normal operation, one or more low-power chips mounted on a second surface of the interposer, wherein the one or more low-power chips generate less than 5 W of heat during normal operation, and the first surface and the second surface are opposite and substantially parallel to each other, and an encapsulating material formed over and configured to encapsulate the one or more high-power chips and the one or more low-power chips.

One advantage of the present invention is that low-power chips and high-power chips are respectively mounted on front side and back side of the interposer, as opposed to existing multi-die packages where high-power and low-power chips are placed on the same side of the interposer. Therefore, the footprint of the interposer and manufacturing cost associated therewith is reduced. In addition, because the interposer thermally insulates low-power chips from high-power chips, low-power chips can be located proximate high-power chips without being adversely affected by the heat generated by high-power chips. Such close proximity and electrical conductive vias running directly through the body of the interposer advantageously shortens the path length of interconnects between the high-power and low-power chips, which improves device performance and reduces interconnect parasitics in the IC system.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments. In addition, the illustration in the appended drawings is not drawn to scale and is provided for illustration purpose.

FIG. 1 is a schematic cross-sectional view of a conventional flip-chip package structure.

FIG. 2A is a schematic cross-sectional view of an integrated circuit (IC) system, according to one embodiment of the invention.

FIG. 2B is an enlarged, fragmentary sectional view showing electrical connections between an interposer and low-power chips.

FIG. 3A is a schematic top view of an integrated circuit (IC) system showing an exemplary positional relationship of an interposer with respect to high-power and low-power chips, according to one embodiment of the invention.

FIG. 3B is a cross-sectional view taken along line A-A of FIG. 3A.

FIG. 4A is a schematic top view of an integrated circuit (IC) system showing an exemplary positional relationship of an interposer with respect to high-power and low-power chips, according to another embodiment of the invention.

FIG. 4B is a cross-sectional view taken along line B-B of FIG. 4A.

FIG. 5 illustrates an exemplary process sequence used to form an integrated circuit (IC) system, according to one embodiment of the invention.

FIG. 6A-6F illustrate schematic cross-sectional views of an interposer at different stages of the process sequence shown in FIG. 5.

FIG. 7 is a schematic cross-sectional view of an integrated circuit (IC) system, according to yet another embodiment of the invention.

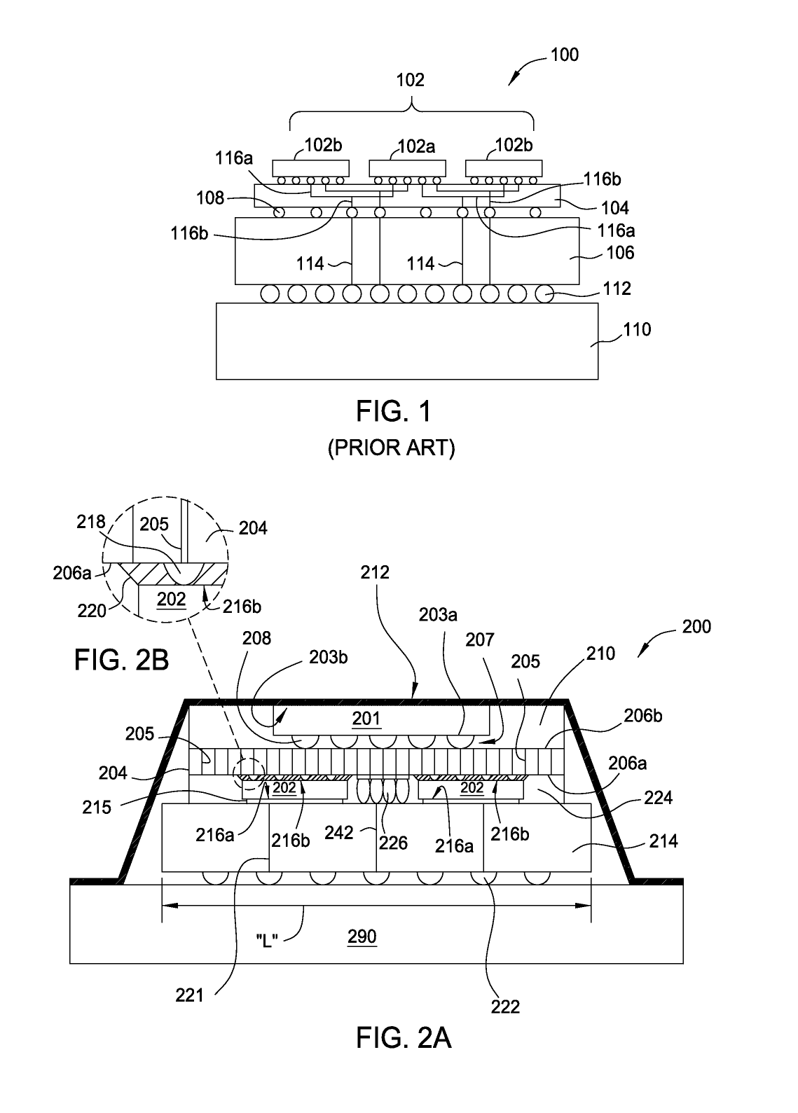

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention provides a system in which one or more low-power chips are mounted on one side of an interposer, while one or more high-power chips are mounted on the other side of the interposer. The interposer has a plurality of electrical conductive vias running therethrough to electrically connect the low and high-power chips. In various embodiments, low-power chips and high-power chips are encapsulated to prevent relative movement between the chips and the interposer due to different thermal expansion coefficients between components. Low-power chips may be positioned in a side-by-side configuration such that each of low-power chips is offset from a center of each high-power chip, allowing faster, direct feed of power from a power source to high-power chips without experiencing resistance losses associated with the low-power chips. In one embodiment, the system may be configured to have one or more low-power chips positioned within a cavity formed in a surface of a packaging substrate to further reduce overall package profile. Details of the invention are discussed in greater detail below.

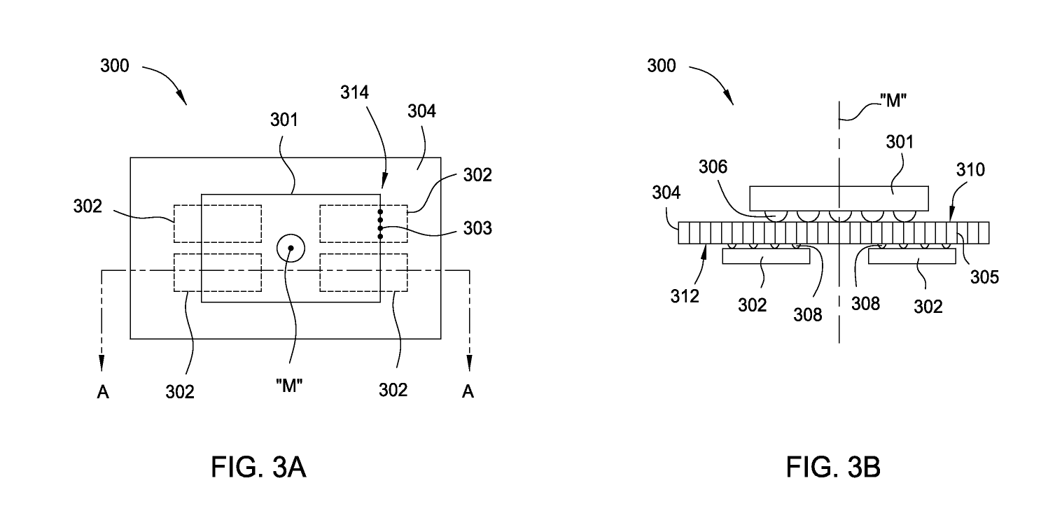

FIG. 2A is a schematic cross-sectional view of an integrated circuit (IC) system 200, according to one embodiment of the invention. IC system 200 includes multiple semiconductor devices, such as IC chips and/or other discrete microelectronic components, and is configured to electrically and mechanically connect said chips and components to a printed circuit board (PCB) 290. As discussed in greater detail below, in various embodiments of the invention, IC system 200 may include a stacked configuration of one or more high-power chips 201, an interposer 204, and one or more low-power chips 202, in which the one or more low-power chip 202 may be flip-chip bumped on a first surface 206a of the interposer 204 while the one or more high-power chips 201 may be bumped on a second surface 206b of the interposer 204. The first surface 206a and the second surface 206b of the interposer 204 are opposite and substantially parallel to each other. The one or more low-power chips 202 are thermally insulated from the one or more high-power chips 201 by the interposer 204 and therefore are not significantly affected by high-power chip 201. Particularly, the footprint of the interposer 204 is reduced since the high-power chips 201 and the low-power chips 202 are respectively attached to the front side and back side of the interposer 204, as opposed to existing multi-die packages where high-power and low-power chips are placed on the same side of the interposer.

The interposer 204 includes a plurality of through silicon vias (TSVs) 205 for stacking up chips. TSVs 205 are adapted to serve as power, ground, and signal interconnections throughout the interposer 204 to facilitate electrical connections between chips that are vertically stacked, for example, high-power chip 201 and low-power chips 202. Specifically, TSVs 205 are “micro vias” running through the interposer 204 to effectively provide vertical electrical connections between high-power chip 201 and low-power chips 202, rather than going through the sidewalls at edges of the chips as typically used in traditional 3D packages. Therefore, TSVs 205 provide very short path-length interconnects between high-power chip 201 and low-power chip 202.

High-power chip 201 may be any semiconductor device operating at high voltages, such as a central processing unit (CPU), a graphics processing unit (GPU), application processor or other logic device, or any IC chip that generates enough heat during operation to adversely affect the performance of low-power chip 202 or passive devices located in IC system 200. A “high-power chip,” as defined herein, is any IC chip that generates at least 10 W of heat or more during normal operation. High-power chip 201 is mounted on a surface of the interposer 204, such as the second surface 206b, and is electrically connected to the second surface 206b of the interposer 204 through electrical connections 207. The electrical connections 207 between high-power chip 201 and the interposer 204 may be made using any technically feasible approach known in the art, including but not limiting to attaching of solder bumps 208 disposed on a side 203a of the high-power chip 201 to bond pads (not shown) formed on the second surface 206b of the interposer 204. The solder bumps 208 may be comprised of copper or another conductive material, such as aluminum, gold, silver, or alloys of two or more elements. Alternatively, such electrical connections may be made by mechanically pressing a pin-grid array (PGA) on the high-power chip 201 into through-holes formed in the interposer 204. If desired, reliability of solder bumps 208 may be improved by protecting the solder bumps 208 with an encapsulant material 210. The encapsulant material 210 may be a resin, such as epoxy resin, acrylic resin, silicone resin, polyurethane resin, polyamide resin, polyimide resin, etc.

The side 203a of the high-power chip 201 is mounted against the interposer 204, and an opposite side 203b of the high-power chip 201 facing away from the interposer 204 is available for a heat sink or other cooling mechanism to be attached thereto. In the embodiment illustrated in FIG. 2A, the side 203b of the high-power chip 201 is thermally coupled to a heat sink 212 to enhance the thermal transmittance of IC system 200.

Low-power chip 202 may be any semiconductor device operating at a voltage relatively lower than that of the high-power chip 201. Low-power chip 202 may be passive devices located in IC system 200, a memory device such as RAM, flash memory, etc., an I/O chip, or any other chip that does not generate enough heat during operation to adversely affect the performance of adjacent IC chips or devices. A “low-power chip,” as defined herein, is any IC chip that generates on the order of about 1 W of heat, i.e., no more than about 5 W, during normal operation. Low-power chip 202 is mounted to a surface of the interposer 204, such as the first surface 206a, by its back surface 216b and is electrically connected to electrical connections on the first surface 206a of the interposer 204 using any technically feasible approach known in the art that is able to establish electrical contact between the interposer 204 and the low-power chips 202. FIG. 2B is an enlarged, fragmentary sectional view showing one embodiment of the electrical connections between the interposer 204 and the low-power chips 202 using microbumps 218. The microbumps 218 may be encapsulated by an encapsulant material 220 to enhance reliability of the microbumps 218. Alternatively or additionally, reliability of the microbumps 218 may be enhanced by an encapsulant material 224 which protects and prevents the entire low-power chips 202 from any relative movement with the interposer 204 and a packaging substrate 214 due to different thermal expansion coefficients between the high-power chip 201, the interposer 204, and low-power chips 202. In some cases where the encapsulant material 224 is used, the encapsulant material 220 may be omitted.

Another side of low-power chip 212, i.e., a front surface 216a, may be mounted to the packaging substrate 214 by any technically feasible approach known in the art, such as solder bumps or a conductive attaching material. In one embodiment shown in FIG. 2A, a die attach material 215 is used. However, the die attach material 215 may be omitted as long as low-power chips 202 remain electrically connected to the packaging substrate 214. For example, low-power chips 202 may be electrically connected to the packaging substrate 214 through solder bumps 226, which are placed between the interposer 204 and the packaging substrate 214 at a region corresponding to the location of the high-power chip 201. In such a case, the solder bumps 226 may be placed between the interposer 204 and the packaging substrate 214 in a middle region underneath the center of the high-power chip 201. The solder bumps 226 are provided to mount the interposer 204 (and thus the low-power chips 202) to the packaging substrate 214. The solder bumps 226 are configured to provide direct delivery of power and/or ground signals from a power source (not shown) through conductive lines 242 to the high-power chip 201 without experiencing resistance losses associated with the low-power chips 202. The solder bumps 226 may use microbumps, or larger bumps such as C4 bumps, to provide effective electrical connection between the high-power chip 201 and the packaging substrate 214. Therefore, the high-power chip 201, the interposer 204, the low-power chips 202, and the packaging substrate 214 are electrically connected to each other in a stacked configuration. In one aspect shown in FIG. 2A, the packaging substrate 214 may have a continuous length “L” that is sufficient to support and encapsulate all low-power chips 202 within the encapsulant material 224, to prevent the packaging substrate 214 from bowing during the encapsulation process or subsequent thermal cyclings.

The packaging substrate 214 is electrically connected to the PCB 290 through conductive lines 221 and packaging leads 222. Packaging leads 222 provide electrical connections between IC system 200 and the PCB 290, and may be any technically feasible chip package electrical connection known in the art, including a ball-grid array (BGA), a pin-grid array (PGA), and the like. While not shown herein, it is contemplated that the packaging substrate 214 may be a laminate substrate comprised of a stack of insulative layers. In addition, conductive lines 221 embedded within the packaging substrate 214 may include a plurality of horizontally oriented wires or vertically oriented vias running within the packaging substrate 214 to provide power, ground and/or input/output (I/O) signal interconnections between high and low-power chips 201, 202 and the PCB 290. The term “horizontal” as used herein is defined as a plane parallel to the plane or surface of the integrated circuit, regardless of its orientation. Also, the term “vertical” refers to a direction perpendicular to the horizontal as defined herein. Packaging substrate 214 therefore provides IC system 200 with structural rigidity as well as an electrical interface for routing input and output signals and power between high-power chip 201, low-power chip 202, and printed circuit board 290.

There are a number of suitable materials widely known in the art for manufacturing laminate packaging substrates used in embodiments of the invention that posses the requisite mechanical strength, electrical properties, and desirably low thermal conductivity. Such materials may include, but are not limited to FR-2 and FR-4, which are traditional epoxy-based laminates, and the resin-based Bismaleimide-Triazine (BT) from Mitsubishi Gas and Chemical. FR-2 is a synthetic resin bonded paper having a thermal conductivity in the range of about 0.2 W/(K-m). FR-4 is a woven fiberglass cloth with an epoxy resin binder that has a thermal conductivity in the range of about 0.35 W/(K-m). BT/epoxy laminate packaging substrates also have a thermal conductivity in the range of about 0.35 W/(K-m). Other suitably rigid, electrically isolating, and thermally insulating materials that have a thermal conductivity of less than about 0.5 W/(K-m) may also be used and still fall within the scope of the invention.

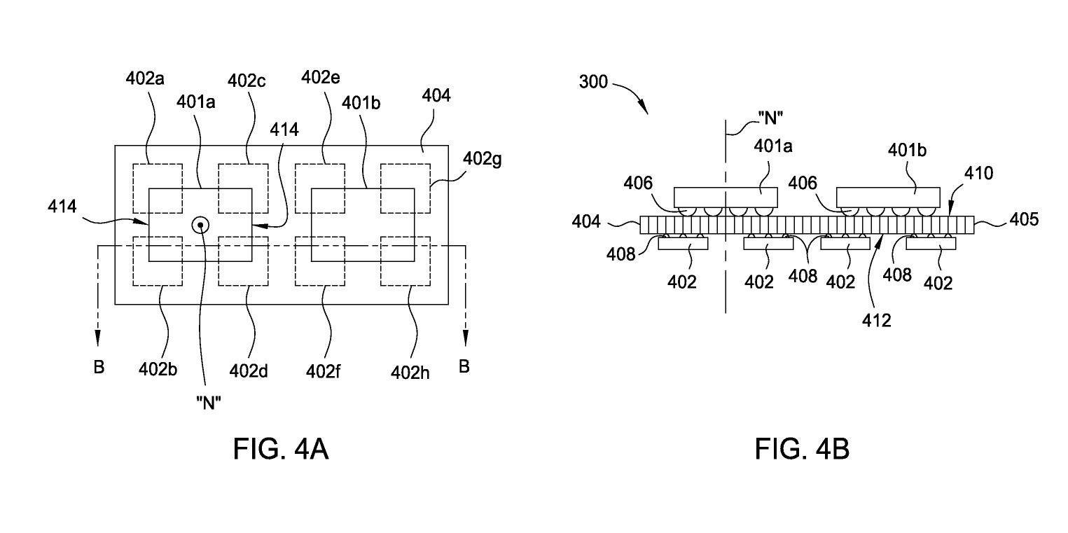

FIG. 3A is a schematic top view of an integrated circuit (IC) system 300 showing an exemplary positional relationship of an interposer with respect to high-power and low-power chips, according to one embodiment of the invention. FIG. 3B is a cross-sectional view taken along line A-A of FIG. 3A. In these embodiments, a high-power chip 301 is mounted onto a first surface 310 of an interposer 304 while low-power chips 302 (indicated by dotted lines in FIG. 3A) are mounted onto a second surface 312 of the interposer 304. The first surface 310 and the second surface 312 are opposite and substantially parallel to each other. The high-power chip 301, the low-power chips 302, and the interposer 304 may be those high-power and low-power chips 201, 202 and the interposer 204 as discussed above with respect to FIG. 2A. Similarly, the high-power chip 301 and low-power chips 302 are respectively mounted to the first and second surfaces 310, 312 of the interposer 304 using any technically feasible approach known in the art as discussed above, such as solder bumps 306, 308. The high-power chip 301 and low-power chips 302 are positioned such that low-power chips 302 are partially overlapped the high-power chip 301. Specifically, low-power chips 302 are positioned in a side-by-side configuration, and each of low-power chips 302 is offset from the center of the high-power chip 301 (“off-center” arrangement) and overlaps an edge 314 of the high-power chip 301 when viewing from a top view, or in a viewing axis “M” normal to the first surface 310 of the interposer 304. In one embodiment, input/output (I/O) terminals 303 of each of low-power chips 302 may be aligned in a row, or may be aligned in a plurality of rows with the edge 314 of high-power chip 301. While only four I/O terminals 303 are shown, it is contemplated that the number of I/O terminals 303 may vary to improve data transfer the processing speed.

Since each of low-power chips 302 is disposed proximate the high-power chip 301 and is only separated by the interposer 304, the path length of interconnects (i.e., TSVs 305) between low-power chips 302 and the high-power chip 301 is very short. This shortened interconnection distance in combination with the “off-center” arrangement of low-power chips 302 allows faster, direct feed of power and/or ground signals from a power source (not shown) to the high-power chip 301 without experiencing resistance losses associated with the low-power chips 320, thereby meeting the power requirement of high current devices. In order to provide such a direct power delivery, one or more electrical interconnects (not shown), which may be in any suitable form, may be used to provide power and/or ground signals directly from a PCB to the high-power chip 301 through the interposer 305. For example, electrical interconnects, such as conductive lines 242 shown in FIG. 2A, may provide direct feed of power from PCB 290 to the high-power chip 201 through a packaging substrate to solder bumps 226 that are in electrical communication with one or more TSVs running through the interposer.

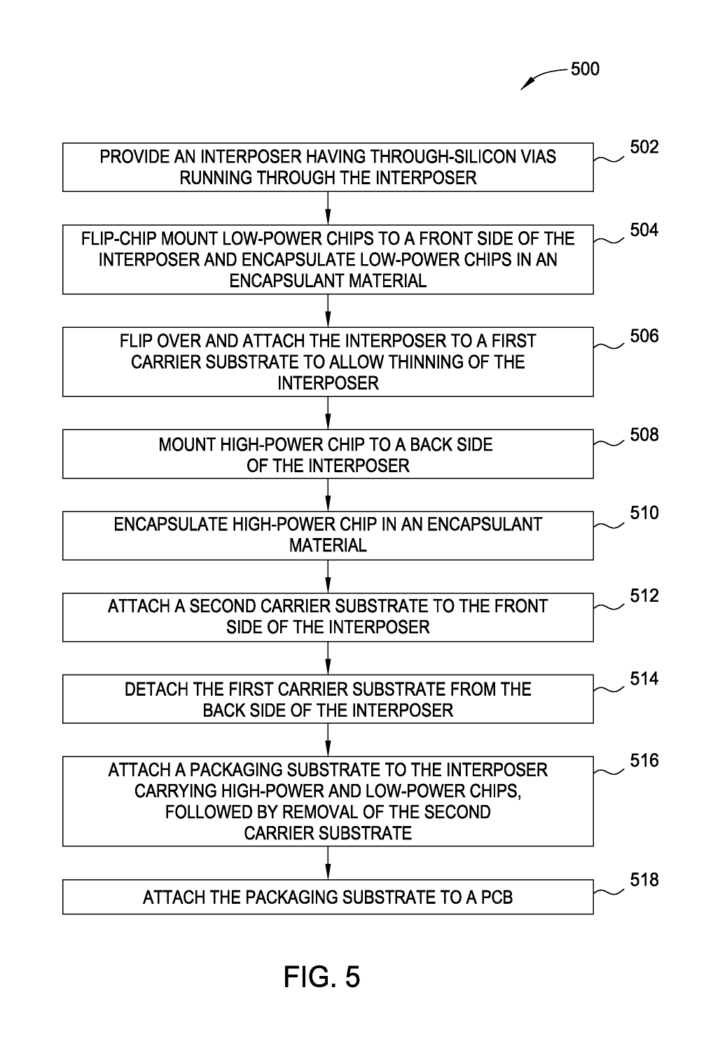

FIG. 4A is a schematic top view of an integrated circuit (IC) system 400 showing an exemplary positional relationship of an interposer with respect to high-power and low-power chips, according to another embodiment of the invention. FIG. 4B is a cross-sectional view taken along line B-B of FIG. 4A. In this embodiment, the IC system 400 generally includes an interposer 404, two high-power chips 401a, 401b mounted on a first surface 410 of the interposer 404, and a plurality of low-power chips (such as eight low-power chips 402a-402h) mounted on a second surface 412 of the interposer 404. The first surface 410 and the second surface 412 are opposite and substantially parallel to each other. Similarly, the high-power chips 401a, 401b, the low-power chips 402a-h, and the interposer 404 may be those high-power and low-power chips 201, 202 and the interposer 204 as discussed above with respect to FIG. 2A, and can be electrically and/or mechanically connected to each other using a suitable manner such as TSVs 405 and solder bumps 406, 408. The high-power chip 401a, 401b and low-power chips 402a-h are positioned such that each of low-power chips 402a-h are partially overlapped the high-power chip 401a or 401b.

Similar to the arrangement and advantageous discussed above, low-power chips 402a-h are positioned in a side-by-side configuration, and each of low-power chips 402a-h, for example low-power chips 402a, 402b, 402c, and 402d, is offset from a center of each high-power chip, for example high-power chip 401a, and overlaps an edge 414 of the high-power chip 401a when viewing from a top view or in a viewing axis “N” normal to the first surface 410 of the interposer 404. In some embodiments, low-power chips 402a-d and low-power chips 402e-h may be configured for use with high-power chip 401a and high-power chip 401b, respectively. If desired, IC system 400 may include additional low-power and high-power chips. It is contemplated that the arrangements illustrated in FIGS. 3A-3B and 4A-4B may vary depending upon the application/chip design and are applicable to the IC system 200 as discussed above with respect to FIG. 2A, or IC systems 600 and 700 as will be discussed below.

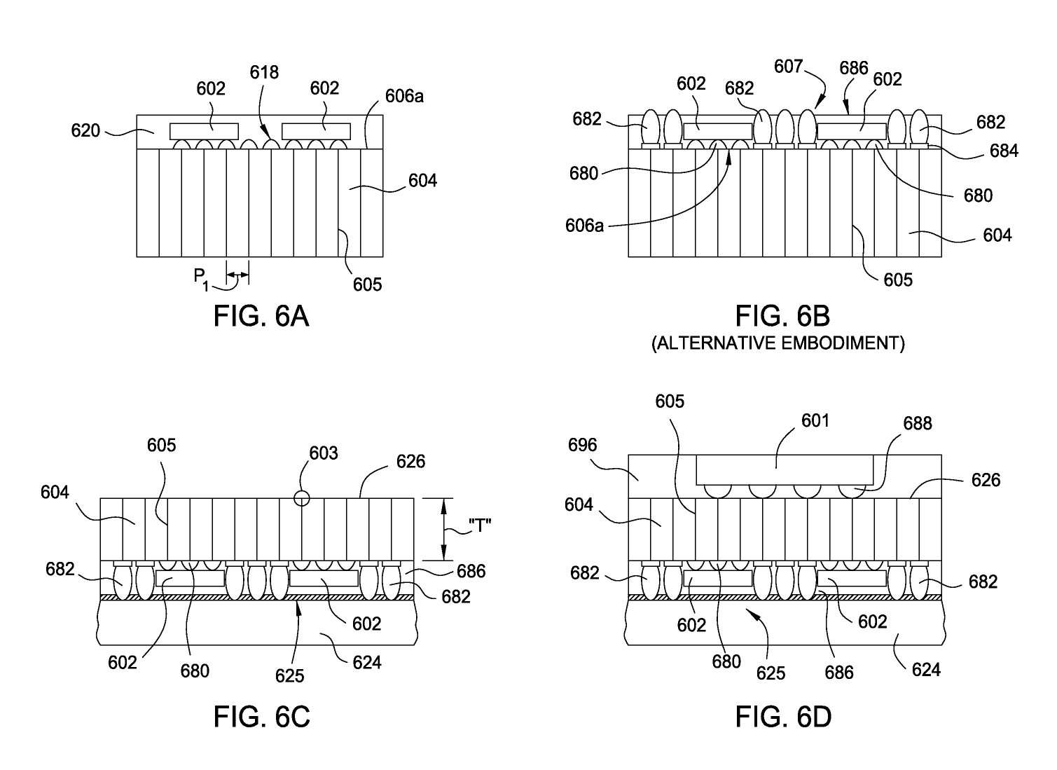

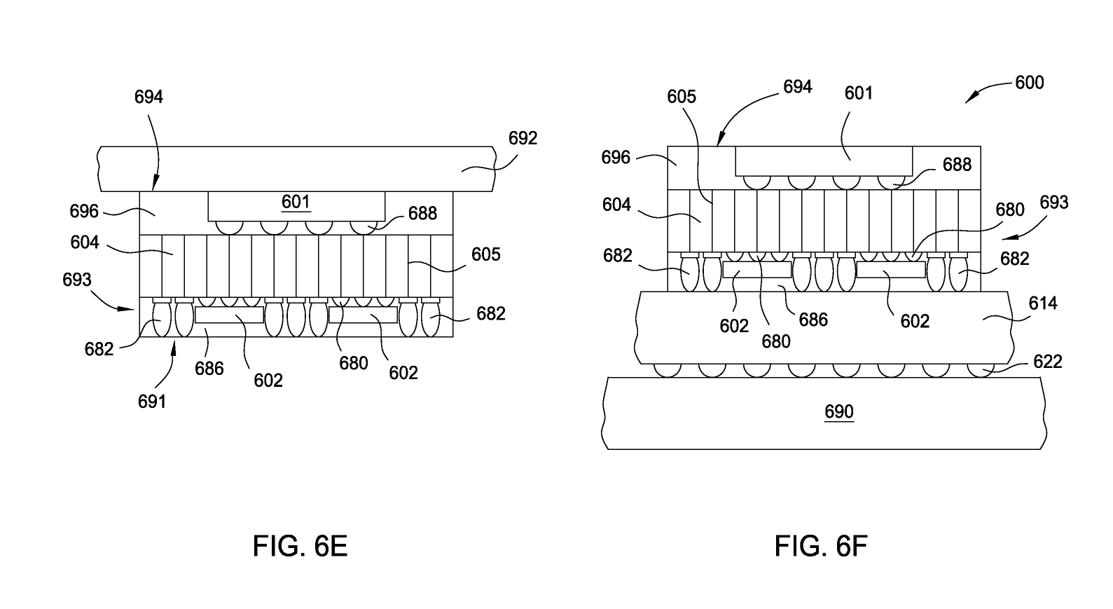

FIG. 5 illustrates an exemplary process sequence 500 used to form an integrated circuit system, such as IC system 200 of FIG. 2A, according to one embodiment of the invention. FIG. 6A-6F illustrate schematic cross-sectional views of an interposer 604 at different stages of the process sequence shown in FIG. 5. It should be noted that the number and sequence of steps illustrated in FIG. 5 are not intended to limiting as to the scope of the invention described herein, since one or more steps may be added, deleted and/or reordered without deviating from the basic scope of the invention.

The process sequence 500 starts at step 502, where an interposer substrate 604 is provided, as shown in FIG. 6A. The interposer 604 may be a bulk silicon-containing substrate having through-silicon vias (TSVs) 605 run through the silicon-containing substrate. In various embodiments, TSVs 605 may be formed with a diameter of about 10 μm to about 20 μm and fully filled with a conductive material such as copper. TSVs 605 typically serve as power, ground, and signal interconnections throughout the interposer thickness and may be manufactured using any existing silicon processing technique in the art. The interposer 604 may have a thickness of less than about 1,200 μm, for example about 800 μm in thickness. The interposer 604 has an array of bump contacts 618, such as microbumps or C4 bumps, formed on a surface 606a of the interposer 604 and each of the solder bumps 618 is connected to TSVs 605. Pitch “P1” of TSVs 605 may be greater than about 50 μm, although in practical design, pitch “P1” may be greater or smaller depending upon application.

In step 504, one or more low-power chips 602, such as low-power chips 202 discussed above with respect to FIG. 2A, are mounted face-side down on the surface 606a of the interposer 604 in a flip-chip manner, as shown in FIG. 6A. The term “face side” denotes the side of the low-power chips 602 that is treated with semiconductor processing such that circuitry is fabricated on that face side of the low-power chips 602. Low-power chips 202 are placed on the surface 606a of the interposer 604 and the bump contacts 618 are heated and reflowed to form solder joints. These solder joints are in alignment with TSVs 605 and are configured to provide an electrical and mechanical connection between low-power chips 602 and the interposer 604. After low-power chips 602 are mounted on bump contacts 618, low-power chips 602, bump contacts 618, and surface 606a of the interposer 604 are encapsulated in an encapsulant material 620 using an underfill process. The encapsulant material 620 structurally couples low-power chips 602 to the packaging substrate (e.g., packaging substrate 214) and prevents or limits differential movement of low-power chips 602 and the packaging substrate during thermal cycling. The high stiffness of the encapsulant material also enables the encapsulant material to accommodate the thermal stresses that would otherwise act on the solder joints. Therefore, the encapsulant material 620 reduces cracking in the bump contacts 620, and extends the life of the solder joints between low-power chips 602 and the packaging substrate. The encapsulant material 620 may be any suitable material such as a liquid epoxy, deformable gel, silicon rubber, or the like, that can be cured to harden. Additionally or alternatively, low-power chips 602 and a portion of surface 606a of the interposer 604 may be encapsulated by an encapsulant material in a similar manner as shown in FIG. 2B without having the entire surface 606a encapsulated.

In yet an alternative embodiment shown in FIG. 6B, the surface 606a of the interposer 604 may be provided with bump contacts including an array of microbumps 680 and an array of C4 bumps 682. C4 bumps 682 may be registered with matching conductive pads 684 patterned on the surface 606a of the interposer 604 and then C4 bumps 682 are reflowed to form solder joints. C4 bumps 682 may be positioned adjacent or around low-power chips 602. Similarly, after low-power chips 602 are mounted on microbumps 680, microbumps 680, C4 bumps 682, low-power chips 602 between the C4 bumps, and surface 606a of the interposer 604 are encapsulated in an encapsulant material 686 such as epoxy or polymeric material using an underfill process. The upper portion 687 of C4 bumps 682 may be exposed through the encapsulant material 686 to facilitate soldering of the interposer 604 onto a carrier substrate used in a subsequent thinning process. The encapsulant material 686 structurally couples low-power chips 602 to the packaging substrate (e.g., packaging substrate 214) and prevents or limits differential movement of low-power chips 602 and the subsequently attached packaging substrate during thermal cycling. The encapsulant material 686 also reduces the fatigue damage on the C4 bumps 682 and/or microbumps 680, and extends the life of the solder joints between low-power chips 602 and the packaging substrate.

In step 506, the interposer, such as the interposer 604 shown in FIG. 6A or the interposer 604 shown in FIG. 6B, is flipped over and attached to a first carrier substrate 624 in a “face-side down” fashion by an adhesive 625, or by an adhesive along with C4 bumps 682 if the interposer 604 shown in FIG. 6B were used. The first carrier substrate 624 provides temporary mechanical and structural support during subsequent thinning process and post processing steps after thinning. The first carrier substrate 624 may include, for example, glass, silicon, stiff polymers, and the like. The adhesive 625 may be any temporary adhesive known in the art that is able to secure the first carrier substrate 624 in a manner suitable to enable subsequent processing. The adhesive 625 should provide adequate mechanical strength, thermal stability, chemical resistance, easy debonding and cleaning. After attaching the interposer 604 to the first carrier substrate 624, a thinning process is performed on a backside 626 of the interposer 604, i.e., the side facing away from low-power chips 602, to achieve a desired thickness of the interposer 604 with TSV tips 603 exposed. The thinning process may be performed using any suitable technique in the art such as an etching process and/or a planarization process. In one embodiment, the interposer 604 may have a thickness “T” of about 50 μm to about 100 μm after thinning. FIG. 6C illustrates the resulting state of the interposer 604 (from FIG. 6B) attached to the first carrier substrate 624 after recessing the backside of the interposer 604.

In step 508, after thinning of the interposer 604, one or more high-power chips 601 are mounted on the backside 626 of the interposer 604, as shown in FIG. 6D. High-power chips 601 may include any suitable circuitry for a particular application. For example, high-power chips 601 may be any of those high-power chips 201 discussed above with respect to FIG. 2A. In the embodiment shown in FIG. 6D, one high-power chip 601 is shown. High-power chips 601 are electrically coupled to the interposer 604 in a flip-chip configuration such that contact pads (not shown) on the high-power chips 601 face the backside 626 of the interposer 604. The contact pads of the high-power chips 601 are electrically connected to the interposer 604 via bump contacts 688 that are formed on the high-power chips 601 and aligned with TSVs 605. Bump contacts 688 may be any suitable conductive means such as C4 bumps.

In step 510, high-power chip 601, bump contacts 688, and portions of backside 626 of thinned interposer 604 are encapsulated in an encapsulant material 690 using an underfill process, as shown in FIG. 6D. The high stiffness of the encapsulant material 690 enables the encapsulant material to accommodate the thermal stresses that would otherwise act on the bump contacts 688, and therefore, reduces cracking in the bump contacts 688 and extends the life of the solder joints between high-power chips 601 and the interposer 604. The encapsulant material 690 may be any suitable material such as a liquid epoxy, deformable gel, silicon rubber, or the like, that can be cured to harden. Additionally or alternatively, high-power chip 601, bump contacts 688, and a portion of backside 626 of the thinned interposer 604 may be encapsulated by an encapsulant material in a similar manner as shown in FIG. 2B without having the entire backside 626 encapsulated.

In step 512, after high-power chip 601 has been mounted on the interposer 604 and encapsulated, the interposer 604 carrying high-power chip 601 and low-power chips 602 (i.e., the semi-finished device 693) is attached to a second carrier substrate 692 by its front side 694 using any temporary adhesive known in the art as discussed above, as shown in FIG. 6E. The front side of the semi-finished device 693 is the side with the high-power chip 601 encapsulated. The second carrier substrate 692 may use the same material as the first carrier substrate 624 to provide adequate mechanical strength and thermal stability, enabling subsequent processing of the semi-finished device 693, such as lifting, transferring, and attaching of the semi-finished device 693 to a packaging substrate.

In step 514, after the second carrier substrate 692 has been attached to the interposer 604, the first carrier substrate 624 is detached from a back side 691 of the semi-finished device 693 by debonding of the termporary adhesive between the first carrier substrate 624 and the semi-finished device 693. Debonding may include any chemical or thermal debonding technique known in the art. FIG. 6E shows a state in which the first carrier substrate has been removed.

In step 516, subsequent to debonding of the first carrier substrate 624, the semi-finished device 693 is lifted and transferred, with the support of the second carrier substrate 692, to attach to a packaging substrate 614 by its back side 691 through C4 bumps 682. C4 bumps 682 are reheated or reflowed to metallurgically and electrically bond the semi-finished device 693 to the packaging substrate 614. The packaging substrate 214 is therefore in electrical communication with high-power chip 601 and low-power chips 602 through the electrical connections, such as bump contacts 688, TSVs 605, microbumps 680, and C4 bumps 682. The packaging substrate 614 may be the packaging substrate 214 as discussed above with respect to FIG. 2A. Thereafter, the second carrier substrate 692 is detached from the front side 694 of the semi-finished device 693, as shown in FIG. 6F.

In step 518, the packaging substrate 614 is attached to a PCB 690 through packaging leads 622, as shown in FIG. 6F. Packaging leads 622 may be any technically feasible chip package electrical connection known in the art, such as solder bumps or BGA, to enable electrical communication between high-power and low-power chips 601,602 and the PCB 690. Therefore, a packaged IC system 600 is provided. A heat sink (not shown), such as the heat sink 212 shown in FIG. 2A, may be placed over and supported by the packaged IC system to enhance the thermal transmittance of IC system. It is contemplated that the heat sink may be of any desired shape and made of any material capable of conducting and dissipating heat generated from the IC system.

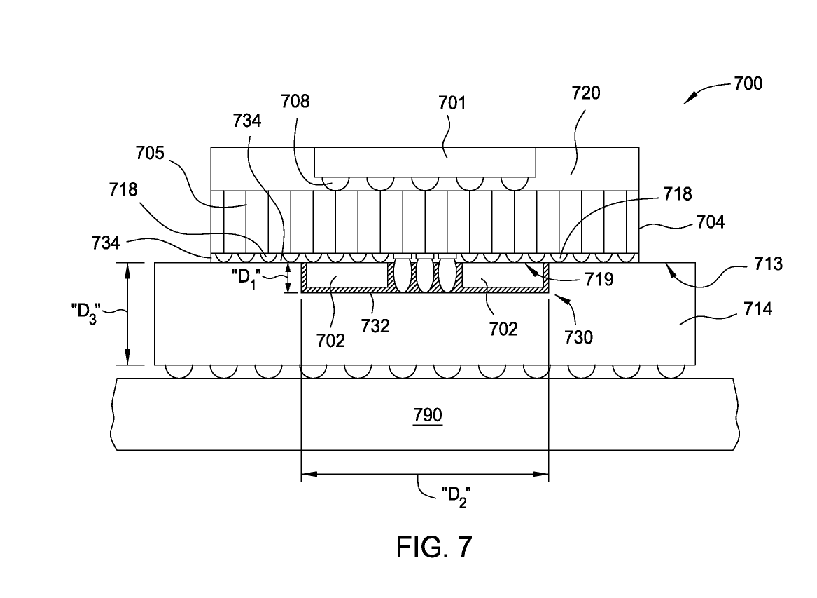

FIG. 7 illustrates a schematic cross-sectional view of an integrated circuit (IC) system 700, according to another embodiment of the invention. IC system 700 is substantially similar in configuration and operation to IC system 200 or IC system 600, except that the packaging substrate 714 of the IC system 700 is provided with a cavity or recessed opening 730 for accommodation of low-power chips 702. The recessed opening 730 can be formed in a top surface of the packaging substrate 714 by any suitable process known in the art, such as wet or dry etching process. The active surface 719 of low-power chips 702, that is, the surface that has a plurality of electrode pads (not shown), may be flush with or slightly above the top surface 713 of the packaging substrate 714. The packaging substrate 714 with low-power chips 702 embedded therein reduces the overall height of the packaging substrate 714, providing a thinner package profile. The active surface 719 of low-power chips 702 electrically connects to electrical connections 718, such as solder bumps, which in turns electrically connects to high-power chip 701 with TSVs 705 running through an interposer 704 and electrical connections 708 such as solder bumps. The recessed opening 730 of the packaging substrate 714 may be filled with a molding material 732 to encapsulate low-power chips 702. Similar to the embodiment shown in FIG. 2A or FIG. 6F, high-power chip 701 may be encapsulated in an encapsulant material 720 using an underfill process. Also, the gaps 734 between electrical connections 718 may be filled or encapsulated in an encapsulant material 724 to prevent low-power chips 702 from any relative movement with the interposer 704 due to different thermal expansion coefficients between the high-power chip 701, the interposer 704, and low-power chips 702. In various embodiments, the recessed opening 730 may have a thickness “D1” of about 20 mm to about 550 mm and a length “D2” of about 20 mm to about 850 mm, and the packaging substrate 714 may have a thickness “D3” of about 20 mm to about 850 mm. It is contemplated that the dimension may vary depending upon the size of the chips.

In sum, embodiments of the invention provide various advantageous over prior art apparatuses, such as thinner package profile due to low-power chips embedded within the packaging substrate. The invention enables overall footprint reduction of the interposer due to stack-up configuration of high-power and low-power chips, as shown in Figures, as opposed to existing IC package in which high-power chip and low-power chip are positioned side-by-side on the same side of the interposer. Low-power chips may be arranged in a “off-center” configuration to allow faster, direct feed of power and/or ground signals from a power source to high-power chip, without experiencing resistance losses associated with the low-power chips. Shorter routing of interconnects between high-power and low-power chips results in faster signal propagation and reduction in noise, cross-talk, and other parasitic in the IC system. The present invention also minimizes heat transfer from high-power chip to low-power chip since heat is transferred and dissipated by heat sink attaching to high-power chip. Furthermore, the interposer disposed between high-power chip and low-power chips acts as a thermally insulating layer to allow low-power chips to be located proximate high-power chip without being adversely affected by the heat generated by high-power chip.

While the foregoing is directed to embodiments of the present invention, other and further embodiments of the invention may be devised without departing from the basic scope thereof. The scope of the different embodiments is determined by the claims that follow.

1. A integrated circuit system, comprising:
an interposer comprising a plurality of electrical conductive vias running through the interposer;
one or more high-power chips mounted on a first surface of the interposer, wherein the one or more high-power chips generate at least 10 W of heat during normal operation;
one or more low-power chips mounted on a second surface of the interposer, wherein the one or more low-power chips generate less than 5 W of heat during normal operation, and the first surface and the second surface are opposite and substantially parallel to each other; and
an encapsulating material formed over and configured to encapsulate the one or more high-power chips and the one or more low-power chips.

2. The system of claim 1, wherein the one or more low-power chips are electrically connected to the one or more high-power chips by the plurality of electrical conductive vias.

3. The system of claim 1, wherein the one or more low-power chips are positioned in a side-by-side configuration.

4. The system of claim 3, wherein each of the one or more low-power chips is offset from a center of each of the one or more high-power chips.

5. The system of claim 4, wherein each of the one or more low-power chips overlaps an edge of the one or more high-power chips.

6. The system of claim 5, wherein each of the one or more low-power chips includes input/output terminals aligned in a row with the edge of the one or more high-power chips.

7. The system of claim 1, further comprising a packaging substrate electrically and mechanically connected to the one or more low-power chips, the packaging substrate has a continuous length that is sufficient to support all low-power chips.

8. The system of claim 7, wherein the encapsulating material encapsulates all low-power chips located between the packaging substrate and the interposer.

9. The system of claim 1, further comprising a packaging substrate electrically and mechanically connected to the one or more low-power chips, wherein the packaging substrate has a recessed opening formed in a top surface of the packaging substrate for accommodation of the thickness of the one or more low-power chips.

10. The system of claim 9, wherein the one or more low-power chips are encapsulated in an encapsulant material within the recessed opening.

11. A method for manufacturing an integrated circuit system, comprising:
providing an interposer having a plurality of electrical conductive vias running through the interposer;
mounting one or more low-power chips on a first surface of the interposer;
mounting one or more high-power chips on a second surface of the interposer, wherein the first surface and the second surface are opposite and substantially parallel to each other; and
encapsulating the one or more low-power chips and the one or more high-power chips.

12. The method of claim 11, wherein mounting one or more low-power chips comprises mounting the one or more low-power chips face-side down on the first surface of the interposer in a flip-chip manner.

13. The method of claim 12, further comprising:
after the one or more low-power chips are encapsulated, flipping over the interposer to attach a back side of the interposer to a first carrier substrate; and
thinning the interposer to obtain a desired thickness of the interposer.

14. The method of claim 13, further comprising:
after the one or more high-power chips are encapsulated, attaching a front side of the interposer with the one or more high-power chips encapsulated to a second carrier substrate.

15. The method of claim 14, further comprising:
detaching the first carrier substrate from the back side of the interposer.

16. The method of claim 11, further comprising:
attaching a packaging substrate to the back side of the interposer having the one or more low-power chips and the one or more high-power chips encapsulated, wherein the packaging substrate has a continuous length that is sufficient to support all low-power chips.

17. The method of claim 16, wherein encapsulating the one or more low-power chips comprise using an encapsulating material to encapsulate all low-power chips located between the packaging substrate and the interposer.

18. The method of claim 11, wherein the one or more low-power chips are positioned in a side-by-side configuration such that each of the one or more low-power chips is offset from a center of each of the one or more high-power chips.

19. The method of claim 18, wherein each of the one or more low-power chips is positioned to overlap an edge of the one or more high-power chips.

20. The method of claim 11, further comprising:
attaching a packaging substrate to the back side of the interposer having the one or more low-power chips and the one or more high-power chips encapsulated, wherein the packaging substrate is configured to provide with a recessed opening for accommodation of the thickness of the one or more low-power chips.
